(19) United States
(12) Patent Application Publication
(10) Pub. No.: US 2007/0251814 A1
(43) Pub. Date: Nov. 1, 2007

(54) Target for a sputtering source

(75) Inventors: Wolfram Beele, Ratingen (DE); Gerald Eschendorff, Te Vendo (NL)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sulzer Metco AG, Wohlen (CH)

(21) Appl. No.: 11/789,514

(22) Filed: Apr. 24, 2007

(30) Foreign Application Priority Data
Apr. 26, 2006 (EP) 06405178.2

(51) Int. Cl. C23C 14/32; C23C 14/00

(52) U.S. Cl. 204/192.1; 204/298.12

(57) ABSTRACT

A target for a sputtering source can be subdivided into a plurality of exchangeable target segments (9). Each target segment (9) contains coating material, wherein each target segment (9) borders on at least two adjacent target segments (9′, 9″), wherein each target segment is connectable to a base body (2, 13, 15) by means of at most one securing means (7, 8, 10).

### CROSS REFERENCE TO RELATED APPLICATIONS

This application claims the priority of European patent application No. 06405178.2, dated Apr. 26, 2006, the disclosure of which is incorporated herein by reference.

The invention relates to a target and to an associated target holder, which is used in a coating method. The coating method includes in particular a gas sputtering method for the application of high-temperature resistant adhesive layers to a substrate, such as in particular to a turbine blade. The target contains the coating material, which can be sputtered from the target in particular by means of ions of an ionised inert gas plasma. The target is accommodated on a target holder in the housing of a coating source. The coating material sputtered from the target reaches the substrate to be coated by means of the flow of ionised inert gas plasma. The coating source is located in a closed vacuum chamber, which is continually pumped down. The ionised inert gas and the deposited coating particles of the target reach the substrate inside the chamber or are pumped off by the vacuum pump. A target is soldered onto a target holder or is screwed directly to the target holder. A possible solution is to bore a blind hole into the target holder, into which the target is screwed. The target is exposed to a high heat input in operation because, on the one hand, a current flow is provided for making available the electric charges for the production of the cathode effect and, on the other hand, the generation and maintenance of the plasma condition of the gas is limited to certain temperature and pressure regions. This heat has to be led away via the target holder. Overheating can occur in the target in temperature ranges above 400° C., not only with a soldered connection but also with a screwed in solution, since the heat can not be led away via the contact surfaces of the soldered connection or of the screw connection. Overheating of this kind results in high residual stresses occurring in the target, which can lead to a crack formation and as a result to premature failure of the target.

It is known from the prior art to bore one or more blind holes into a target base body. The target base body is formed as a disc of a coating material, into which cylindrical targets are introduced, into blind holes by means of a shrink fit.

A blind hole of this kind always only borders onto the base body or in other words onto a single part. A problem, which occurs when using this prior art is that, due to differential thermal stresses, it can not be guaranteed that the bond between the target base body and the cylindrical targets can be maintained. A further problem of this embodiment is the need to form bores in the target base body, which results in a not inconsiderable loss of material. In coating materials which contain the rare earths, platinum, titanium or similar materials, the cost of the material is hardly negligible.

A further disadvantage resides in the fact that the base body with the cylindrical target can only be removed as a whole.

A further disadvantage resides in the fact that, with the combination of the base body and the cylindrical target, the composition of the coating is essentially fixed and an alteration of the same is only possible by replacement of the base body and/or of the cylindrical target.

A sputtering target is known from DE 44 26 751 A1 which is used in a cathode sputtering process. From a certain area size of the sputtering target onwards alterations in the length occur due to the expansion of the sputtering target on heating of the same, through which heat stresses in the sputtering target result, which is fastened to a target back plate. These thermal stresses can lead to damage to the sputtering target and/or to the target back plate, in particular in sputtering targets with a large extent. For this reason it is proposed in DE 44 26 751 A1 to assemble the sputtering target from individual segment bodies which are spaced from one another in a non-heated condition, and which just touch each other in a heated condition. A disadvantage of this known solution is the fact the distances of the segment bodies have to be newly determined for each combination of materials. A further disadvantage of this solution is the need for a plurality of securing points per target segment. In this case the thermal stresses between the securing points also have an effect such that cracks or fractures arise in the region of the securing points, in particular if brittle material is used for the target material or sintered or pressed powders which do not have adequate compressive and/or tensile strength. A further disadvantage of the known solution is caused by the small heat exchange surface between the target segment and the target back plate connected to a cooling system, since the heat has to be dissipated essentially via the screw connection. In accordance with one embodiment the sputtering target together with the target back plate is, moreover, “swimmingly” mounted on the cathode body, i.e. displaceably mounted parallel to the sputtering target surface. The thermal stresses arising due to the securing are admittedly lessened by means of this measure, however, the thermal dissipation into the cooling system is also reduced.

Another problem in connection with the use of target segments is described in DE 197 38 815 A1. The use of target segments requires special assembly solutions, in particular if it is to be guaranteed that a target segment lies arealy on a cathode plate, in order to improve the above-described deficient heat transfer. The assembly solution presented in DE 197 38 815 A1 admittedly also requires the use of adjusting bolts for positioning the target segments. However, it follows from this that at least a second securing possibility per target segment has to be present, since the adjusting bolt only undertakes the task of the centring and positioning of the target segment. Thus, with respect to the thermal stresses introduced into the target segment, precisely the same problems occur as have been already been explained in connection with the target segment arrangement presented in DE 44 26 751 A1.

Furthermore it is known from DE 102 27 048 A1, to manufacture a hollow cathode from a plurality of targets, whereby at least 4 targets are foreseen, which form the side surfaces of a prism. An advantage of this arrangement, in comparison with a cylindrical hollow cathode, is the easier manufacture of the target plates. These target plates are fastened with a central screw to a cooling body, such that the target plate touches the cooling body on its backside over the total surface, but is fastened only in a point centrally. It is the aim to use the heat exchange surface optimally, however, there are heat losses at the screw. These heat losses may cause a deterioration of the heat transfer, in particular with the use of small targets. No reference is made also in this publication to the limited current flow. The current has to be delivered to the target via the screw. The power density is therefore limited by the cross-section of the screw or the support surfaces in the thread under the assumption of an incomplete screwing. Tests with a comparable arrangement making use of MCrAlY or NiAl targets have shown, that broken and/or bent targets have been observed already at a temperature of roughly 900° C. and a coupling power of maximum 5 kW (up to 15 W/cm²). In this case, the targets were fixed with a clamp connection. Targets melted at a coupling power of maximum 10 kW (up to 21 W/cm²), if they were directly screwed to the cooling body as described in DE 102 27 048 A1. The targets got too hot and were therefore damaged.

It is therefore the object of the invention to provide a target which includes target segments which are connected to the cooling system by means of a target holding apparatus in such a way that no thermal stresses are introduced into the target segment, and also an adequate thermal dissipation is provided. It is a further object of the invention, to increase the coupling power as well as the power density, in order to decrease the duration of a coating procedure.

The satisfaction of the object takes place by means of the characterising part of claim 1. A target for a sputtering source can be subdivided into a plurality of exchangeable target segments, wherein the target segment contains coating material and each target segment borders on at least two adjacent target segments, and is characterised in that each target segment is connectable to a base body by means of one securing means at most.

One target segment stands for one element of coating material, which is located in a coating source, which is for use in a coating method, such as in particular a gas sputtering method. A coating apparatus is used for the coating method, which includes the coating source and also the substrate to be coated. The coating source includes all of the target segments, the target holding apparatus for each target segment, a distribution apparatus for a gas, which includes an inert gas, in particular argon or a reactive gas, in particular an oxygen containing gas. The coating source further includes a cooling body with coolant connection, in particular a water connection and a housing for receiving all the above-named components and and also means for the insulation of the whole coating source. These means for insulation bring about the complete electrical and largely complete thermal insulation of the coating source from the sputtering space. The sputtering space is the term used to describe the region of the coating apparatus, which is mostly formed as a vacuum chamber, in which the coating takes place, that is to say the component or components to be coated are located in this region of the vacuum chamber. The coating material is arranged on the target segment. The coating source is used in particular in a gas sputtering method, for which in the following the abbreviations GV-PVD (gas flow physical vapour deposition) or also HS-PVD (high speed physical vapour deposition) are to be used. Two target segments lying opposite one another are mostly used for the gas flow sputtering method. Depending on the size and desired sputtering rate, these target segments can be designed as an individual element or can be composed of a plurality of individual segments, precisely the aforementioned target segments. Thus, in this application, the expression target segment instead of target means that at least one target segment is used per target holding apparatus. The segmenting of the target permits the achievement of higher coating rates and of the coupling in of power. Should higher coating rates and the coupling in of power be of secondary significance, work can also carried out without segmenting using the present arrangement of the coating source in the sputtering method. By means of the use of target segments it is possible a couple in a higher electrical power into each target segment, through which the sputtering of layer material from the target segment is accelerated, so that a higher sputtering rate can be achieved. The use of target segments also offers advantages which relate to the durability and mechanical characteristics of the target segments. Due to the lower stresses in each target segment cracks and fractures in the coating material do not occur. Furthermore the temperature resistance of the arrangement of the target segments increases because the heat can be better dissipated, by means of which there is no melting of the material on any of the target segments. Each of the target segments has its own power connection in particular as well as its own connection to the cooling body. The primary function of the cooling body is to dissipate the heat arising on the target segments during the coating procedure. The power input which, caused by currents, in particular up to 150 A per target, provokes power densities in particular up to 220 W/cm², and also the impact energy of the gas atoms striking the target segment produce the thermal energy to be dissipated. On the one hand, in a coating procedure for coating with a metallic coating material, an inert gas can be used and argon has proved to be suitable in particular. The impact energy of these argon atoms likewise leads to an introduction of heat into the target segment. By means of the impact atoms of the coating material are loosened out of their bond on the target surface. High temperatures are reached during this. In order to control the process better, there can be additional heating by means of a radiation heating apparatus, in order to attain coating temperatures according to the substrate and the layer of, in particular, up to 1150° Celsius in the coating chamber. The coating apparatus can also be used for a reactive gas sputtering method. Instead of or in addition to an inert gas, a reactive gas, in particular gas containing oxygen is added, by which means reactions of the coating material with the gas molecules at the target segment or in the gas phase following release from the target segment can result, so that an increase in temperature results through the mainly exothermally proceeding chemical reactions, in particular oxidation reactions. In order to avoid an overheating of the target segments with a coating duration of a few hours, each target segment is cooled, with water cooling being used in particular. For the coupling in of higher currents, which result in a higher heat transfer at the target segment, it is advantageous to use a plurality of individual target segments in the coating apparatus. In order to avoid the above-named stresses in the coating apparatus or to minimize them to such an extent that they are below the crack forming stress level of the target segment material, the target holding apparatus in accordance with the invention described in the following is used.

The coating source thus includes the target segment or target segments, the power connection for each of the target segments, a connection of each of the target segments to the cooling system for the supply and removal of a coolant. The supply of the inert gas and/or of the reactive gas takes place via gas connections, and also gas distributors which are arranged in such a way that an even distribution of the quantity of gas takes place on all target segments at the same mean impact speed. Apparatus-wise, each target segment is included in a target holding apparatus. The target holding apparatus includes the cooling body or cooling bodies, and an outer wall and connection means to attach the target segment onto the cooling body and also to the outer wall of the coating source.

A further advantage resides in the possibility of dismantling the target segments individually after conclusion of the coating process, when the coating material has been used, in order to provide them with coating material again within the scope of a refurbishing step.

When using small segments, the residual stresses in the target segment are limited, so that brittle and poorly combinable coating materials and/or coating material combinations can be used. With high thermal loads target segments with small dimensions can, moreover, be selected, so that the proportion of heat which can be dissipated via the securing apparatus increases. This improvement of the thermal transfer is based on the fact that the heat exchange surface is larger in comparison with the heat exchange surface in accordance with the prior art, because the securing apparatus has a larger common surface relative to the target segment. Moreover, the thermal transfer can be improved by the use of contact lamellae to such an extent that the limiting factor for the thermal transfer is no longer the dissipation of the heat from the target segment to the cooling body, but rather the thermal transfer is limited by the performance of the cooling body.

A further advantage is the possibility of restoring the targets (by means of HIP, spraying processes) wherein the tongue and groove connection at the target is preserved.

When using small segments the residual stresses in the target are limited, so that higher power inputs become possible. The thermal stress at the target also sinks due to the increase in surface area.

The use of an individual securing apparatus per target contributes to the reduction of the residual stresses, so that the use of brittle and hard coating materials is possible.

Further advantages embodiments of the invention are the subject of the auxiliary claims.

In accordance with an advantageous embodiment for the target for a sputtering source the securing means includes electrically and/or thermally conductive means, so that in the operating state a uniform current strength can be distributed across the surface of the target segment also the heat arising on the target segment can be dissipated uniformly into the base body.

In accordance with an advantageous embodiment for the target for a sputtering source, the securing means include a plug connection.

In accordance with an advantageous embodiment for the target for a sputtering source, a plug connection is provided for a plurality of target segments.

In accordance with an advantageous embodiment for the target for a sputtering source, the base body includes a cooling body, to which each target segment can be electrically and thermally coupled.

In accordance with an advantageous embodiment for the target for a sputtering source, each target segment is completely comprised of coating material. The target segments are kept free of thermal stresses through the possibility of compensation of the thermal stresses by the provision of resilient contact elements.

In accordance with an advantageous embodiment for the target for a sputtering source, one target segment includes at least a first layer material or a first combination of layer materials, which differ from the layer material or from the combination of layer materials of a second target segment.

The target in accordance with one of the previous embodiments is used in particular in a coating source for a gas sputtering method.

A method for the coating of a component including a sputtering source, a target and also a gas for the transport of sputtered coating material to the component includes the steps of: contact of a gas with the target surface, the release of particles out of the target surface, transport of the released particles with the flow of gas, coating of the component with particles from the flow of gas, wherein the flow of gas proportionally releases the particles for the component to be coated from each target segment.

The particles include charged particles, such as in particular ions and/or neutral particles, such as atoms in particular.

For carrying out the sputtering method the sputtering source includes a target, which contains the previously described target segments, impact producing means, in other words in particular gas atoms and/or ions, and also moving means, in particular a moving stream of gas are required. The impact producing means contact the target in order to release particles from the surface of the target through its impulsive impact on the target surface by means of the impact energy of the incident impact producing means. A movement means serves for the transport of the sputtered particles from the sputtering source to a component to be coated.

In particular, in accordance with the previously described method, particles are released from the target segments by the flow of gas in such a manner that the proportion of the different layer materials or layer material combinations on the component corresponds to the proportion of the target segments with corresponding layer materials or layer material combinations on the target, so that the component is proportionally coated with a first layer material or a first layer material combination of a first target segment and with a second layer material or a second layer material combination of a second target segment.

In particular the proportion of different layer materials or layer material combinations sputtered by the flow of gas is altered according to an advantageous embodiment by a gas distribution unit, which is movable relative to the target.

The gas used in the previously described method includes in particular an inert gas, in particular argon and/or is formed as a quasi neutral plasma.

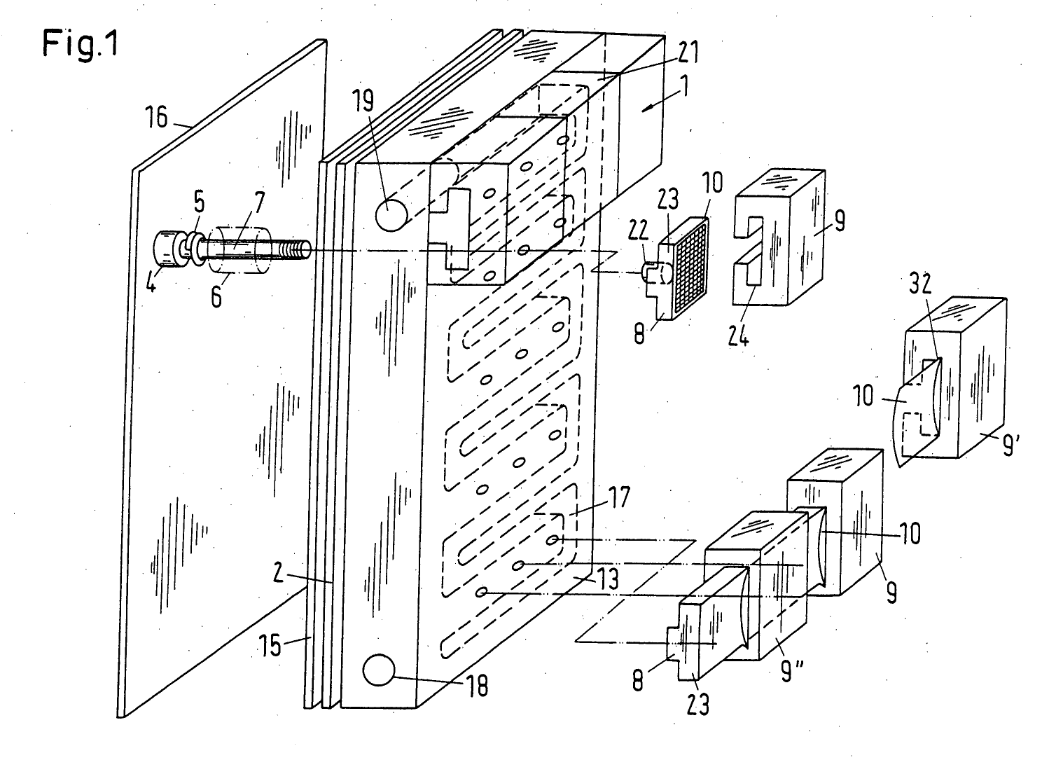

FIG. 1 shows a layout of a target holding apparatus in accordance with a first embodiment.

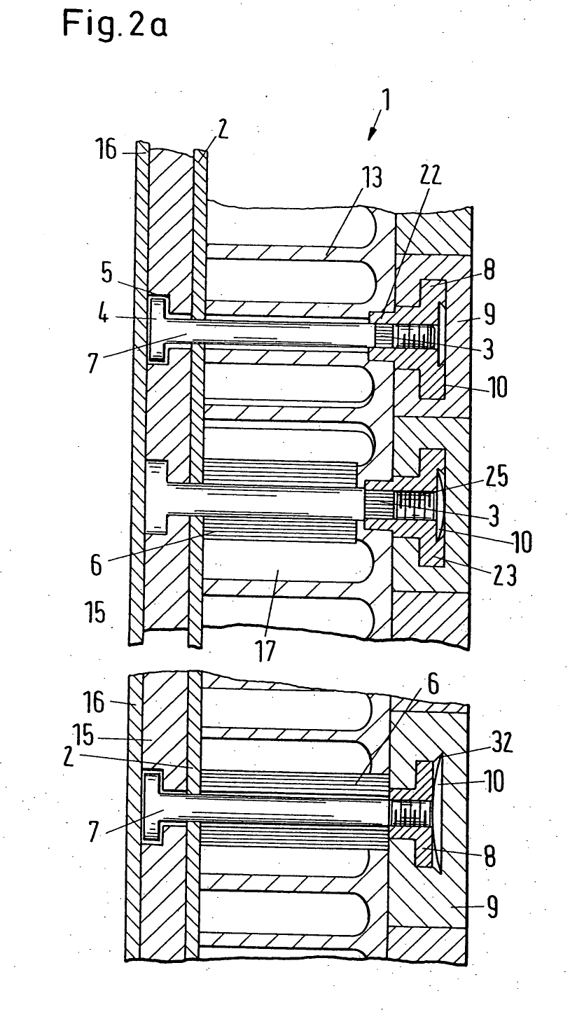

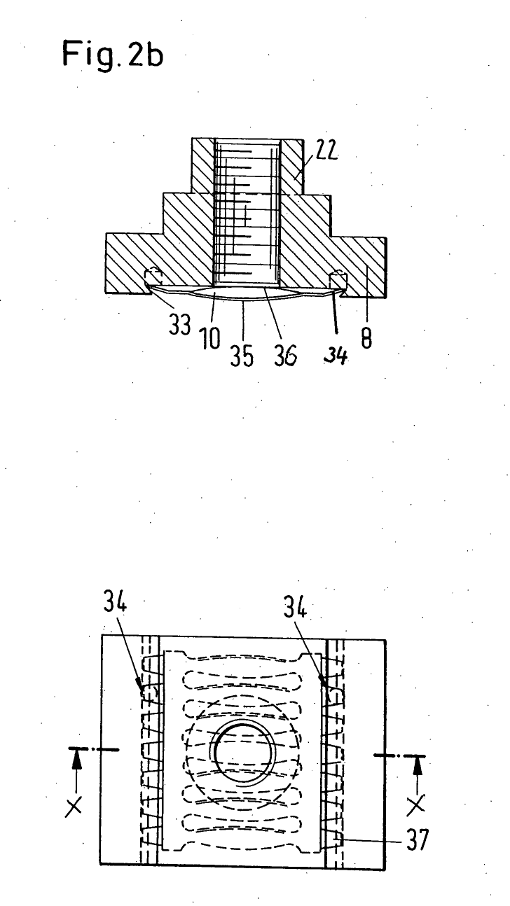

FIG. 2a shows a section through the target holding apparatus in accordance with FIG. 1.

FIG. 2b shows a T-nut with a groove into which a contact lamella is pushed, wherein the upper illustration is a sectional side view taken along the lines as indicated by arrows X in the lower illustration.

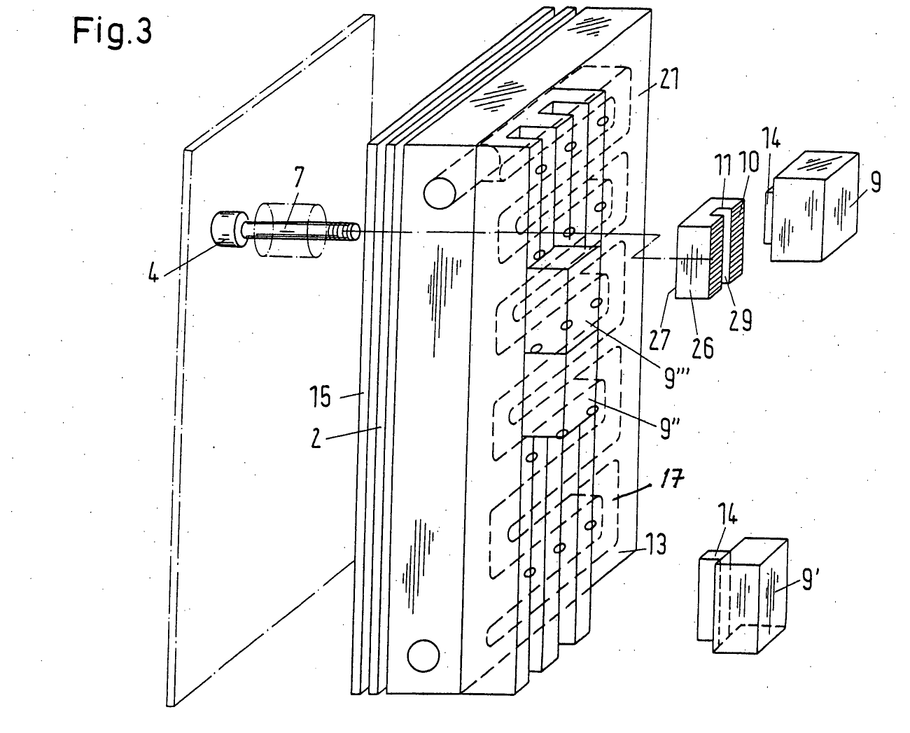

FIG. 3 shows a layout of a target holding apparatus in accordance with a second embodiment.

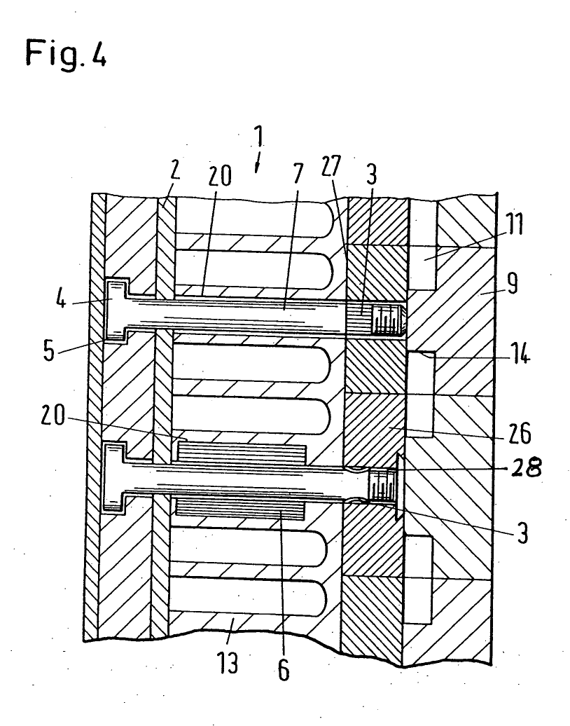

FIG. 4 shows a section through a target holding apparatus in accordance with FIG. 3.

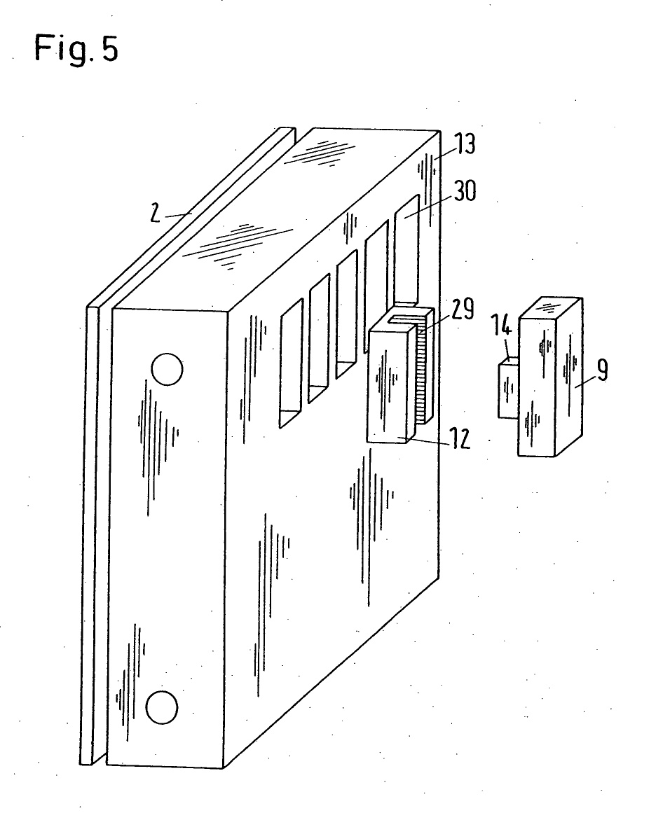

FIG. 5 shows a layout of a target holding apparatus in accordance with a third embodiment.

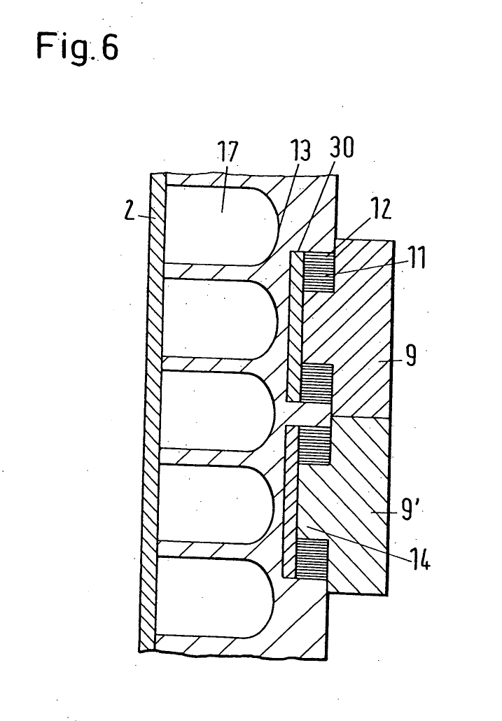

FIG. 6 shows a section through the target holding apparatus in accordance with FIG. 5.

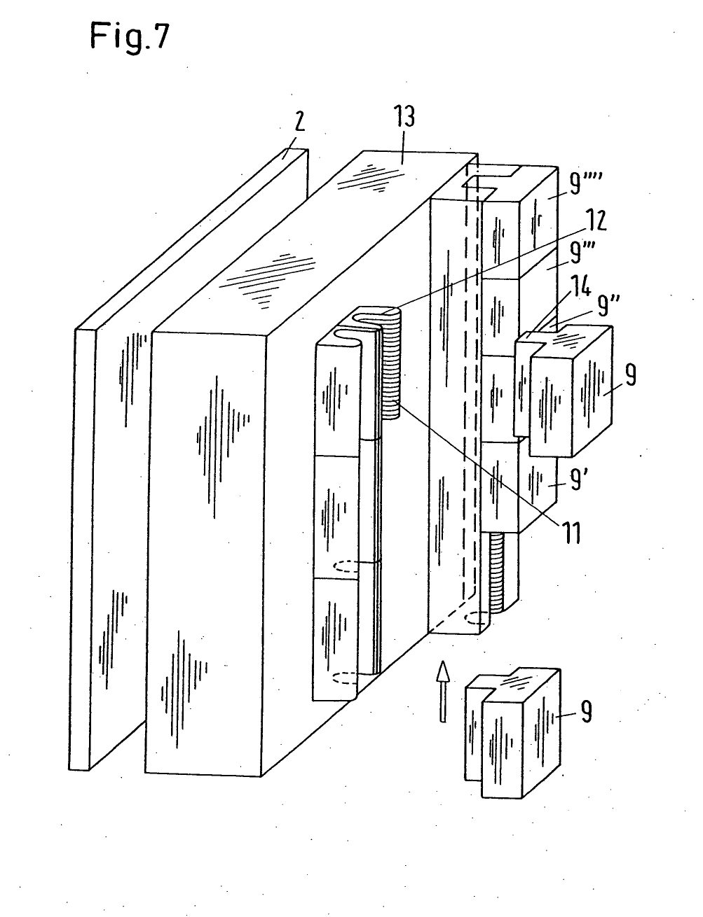

FIG. 7 shows a layout of a target holding apparatus in accordance with a fourth embodiment.

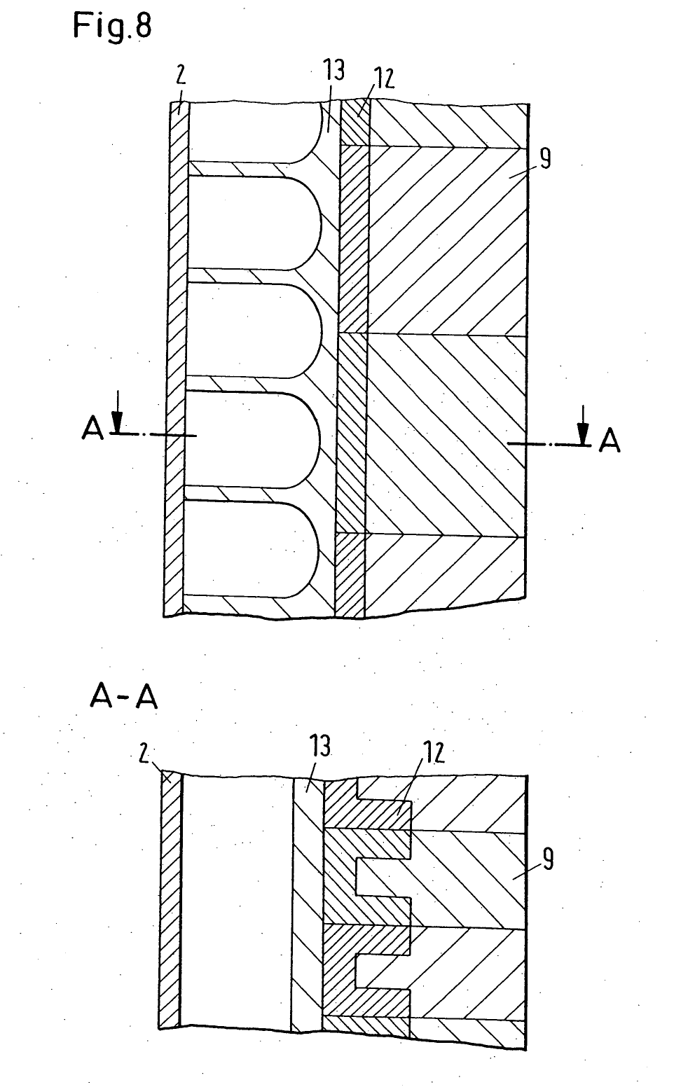

FIG. 8 shows a section through the target holding apparatus in accordance with FIG. 7.

FIG. 1 shows the arrangement of a target segment 9 which is secured in the coating source to a target holder 1. Each target segment 9 is screwed to the cooling body outer wall 2 by means of a T-nut 8. The T-nut includes a cylinder 22 and an appended part 23, which has a T-shaped cross-section. The cylinder 22 is received by a bore in the cooling body 13. The T-shaped appended part 23 projects beyond the surface of the inner side of the cooling body 21. A contact lamella 10 of low-alloyed copper or nickel, in particular of CuBe, CuCoBe or NiBe is attached to the T-nut and/or a galvanic coating is applied. At least one target segment 9 is plugged onto the T-nut 8, with the T-nut and the target segment having an intermediate space in which the contact lamella 10 is arranged. In FIG. 1 the target segment 9 is plugged onto the T-shaped appended part 23. A groove 24 is provided in the target segment, which is broadened to the shape of a T, which is designed to match the shape of the appended part 23. The T-shaped appended part 23, which engages into an associated groove 24 of the target segment 9, can serve to receive at least one target segment 9. A possible variant is illustrated in FIG. 1 in which a T-shaped appended part 23 serves to receive a plurality of target segments 9. A target is pushed into its position on the T-shaped appended part 23 in the same way as the target segments already plugged into place, with the number of the target segments per T-nut being dependent on the width of the segment, which in turn is in direct relation to the size of the source. The target segments are all plugged onto the T-nuts and/or associated contact lamellae and/or associated galvanic coatings. Each of the target segments 9 is received in a counter-shape corresponding to the shape of the appended part 23, with a groove in the form of a T being shown in FIG. 1. However, other form-locked connections can be used, by means of which the T-nuts and/or the contact lamellae can be embraced, at least in part. In particular a dovetail groove can be provided in the target segment 9. A contact lamella 10 is arranged in the groove of the target segment 9. The contact lamellae and/or the galvanic coatings conduct the heat from the target segment in the direction of the cooling system as a result of their good heat conducting characteristics. For the improvement of the heat transfer from the target segment 9 to the contact lamellae 10, a galvanic coating can also be provided on the contact lamellae. The galvanic coating is in particular located on the surface of the contact lamellae 10 facing the target segment or segments 9 when the contact lamellae are held in the T-nut. When the contact lamella is received in the target segment 8 the galvanic coating is on the side of the contact lamella facing the T-nut. The atoms and/or ions of an inert gas impact on the target segment 9 in operation, in other words during the coating process. They knock atoms out of the target segment material. By means of the impacts of the ions striking on the target segment material thermal energy is carried into the target segment 9, which is carried off to the cooling body 13 via the contact lamellae 10, the T-nut 8 and also the attachment screw 7.

In FIG. 2a the target holder 1 from FIG. 1 is illustrated in section. In FIG. 2a the attachment screw 7 is only illustrated in the upper part of the drawing, in the lower part the attachment screw 7 is left out, in order to increase clarity. The lowest shown attachment screw in FIG. 2a shows a simplified variant, when a positioning of the T-nut in the cooling body is not necessary due to the cylinder 22 of the T-nut 8 projecting into the interior of the cooling body 13. This variant can be used when the target only consists of a small number of a target segments or when the position of the target segment is already determined by adjoining target segments. Adjoining target segments can touch each other when the temperature load is too low to cause a noticeable thermal expansion or when the target segments are composed of a coating material or of a combination of coating materials, the thermal expansion of which is negligible, i.e. less than 0.5 mm, in particular less than 0.1 mm, preferably less than 0.05 mm. In the variant shown right at the bottom in FIG. 2a it is furthermore shown that the target segment has a recess 32 in the groove 24 in order to receive a contact lamella 10.

The size of a target segment can be adjusted in such a way that at the desired power input the target segment has such small length, breadth and also depth dimensions that the maximum possible heat input via the target segment surface, which is exposed to the flow of gas, remains limited. The securing apparatus is dimensioned in such a way that all the heat can be led away via the T-nut 8 or the forked plug device 12 and/or via the attachment screw 7 with the associated contact lamella 3, so that the cooling capacity of the cooling system designed as the cooling body 13 becomes the limiting factor for the heat transfer.

Through each of the illustrated contact lamellae 10 not only is an improvement of the thermal transfer achieved by the enlargement of the thermal transfer surface but also a compensation of the thermal stresses of the temperature loaded target segment. The contact lamella 10 acts as a spring mechanism the function of which consists of resiliently taking up the thermal expansion effects of the coating material, by means of which the gap spacings known from the prior art and other solutions, which include dowel pins, are no longer needed. The use of the contact lamellae 10 also has the advantage that the connection to the heat dissipation through the cooling body 13 and the connection to the power transmission take place in a uniform manner for the duration of the entire coating process. It can be guaranteed by means of the contact lamellae that the power transmission and also the heat dissipation can take place in a largely constant manner time-wise by thermal conduction, whereby a sputtering process is made possible which takes place under consistent conditions for both power transmission and heat dissipation. A flexible foil can be used as a contact lamella.

A contact lamella which can be routinely obtained can also be used to advantage, as is illustrated in FIG. 2b. The contact lamella 10 is pushed into a groove 33 of the T-nut 8 and can be received in this groove under prestress and/or can be secured against axial displacement via a locking element. To increase the pre-stress, a contact lamella can include first regions 35 which are supported in the installed state on the surface of the T-nut spanned by the contact lamella and also second regions 36 which maintain a contact with the target segment in the installed state. Moreover the heat dissipation takes place by means of thermal conduction from the target segment to the T-nut via the second regions 36 and/or via the first regions 35 and also via the rib 37 received in the groove. The heat conduction via the contact lamella and the T-nut takes place so fast that the amount of heat to be led away is limited by the cooling capacity of the cooling body. Thus, through the use of the contact lamella not only does a uniform contact for the input of the electrical current into the target segment result but also an improved heat transfer. Since the contact lamella acts as a spring mechanism, any desired pre-stress can be set depending on the design of the contact lamella. On the one hand, the possibility exists of varying the wall thickness of the contact lamellae, on the other hand, the proportion of the first and second regions (35, 36) can be varied in order to achieve an exactly defined and reproducible pre-stress. The contact lamella is then preferably deformed in the elastic region so that it can be used for repeated assembly and dismantling cycles.

In the interior of the part of the T-nut 8 formed in particular as a cylinder 22 there is located an internal thread 25, as is illustrated in FIG. 2a. The external thread of the attachment screw engages into the internal thread 25. The attachment screw consists in particular of copper or low alloy copper, such as CuBe, CuCoBe, CuTeP. The two securing solutions illustrated in the lowest part of FIG. 2 show the installation of a sleeve 6 as a modification of the upper part. This sleeve 6 is additionally used for the removal of the thermal energy to the cooling body and is also termed a screw-in lamella or screw-in lamella sleeve in specialist literature. The chief function of the sleeve 6 is to improve the thermal and electrical contact between the attachment screw 7 and the cooling body 13. The sleeve 6 is screwed into the cooling body 13 or plugged onto it so that a good heat transfer is guaranteed by the connection, which is designed in particular as a screw connection or as a press fit.

For the further illustration of the connection of the target segment 9 to the cooling body reference is again made to FIG. 2a. The connection of the target segment 9 to the cooling body 13 and to the power contact, which is not illustrated, is effected here through the contact lamellae between the target segment 9 and the surface on the target segment side of the appended part 23, through the rear side target segment surface of the target segment 9 to the T-nut 8, via the T-nut and the internal thread 25 of the cylinder 22 of the T-nut to a contact lamella 3 arranged in the internal thread 25 and also from it into the attachment screw 7 and also from the attachment screw 7 directly to the cooling body or alternatively to this via the sleeve 6 to the cooling body 13. The contact lamella 3 is either part of the attachment screw 7 as illustrated in the upper part of FIG. 2a, or is part of the cylinder 22 of the T-nut 8, as is illustrated in the lower part of FIG. 2a. The sleeve 6 is illustrated in FIG. 2a with direct contact to the coolant, which flows through the cooling passages 17. The insulation of the coating source against discharges to the outer sides takes place by means of an isolating zone 16. The isolating zone 16 is located at the outer wall 15, which also contains recesses for the screw heads 4 of the attachment screws 7.

In a further embodiment in accordance with FIG. 3 and FIG. 4 the connection of the target segment 9 to the cooling body 13 and to the power contact, which is not illustrated, is effected by means of a connector 26. The connector 26 contains an internal thread 28 at its surface on the cooling body side, which serves to receive an attachment screw 7, which is made the same as the attachment screw from the embodiment in accordance with FIG. 1 or FIG. 2a. The connector 26 includes a contact lamella 27 and/or a galvanic coating at its surface at the cooling body side for increasing the current and/or heat transfer. In this arrangement the contact lamella 27 does not need to be restricted to the internal thread 27, but is able to encompass the entire contact surface. The advantage is that heat can be transferred directly from the connector 26 to the inside of the cooling body 21. The coolant passages 17, which are illustrated in FIG. 3 as a non-visible element, are located in the illustrated variant in the direct vicinity of the surface of the connector 26 on the cooling body side and its contact lamella 27 and/or its galvanic coating. The contact lamellae 11 are provided in a slit-like recess 29 between the target segment 9 and the surface of the connector 26 at the target segment side. The recess 29 serves to receive a rib 14 of the target segment 9, which is intended for engagement into the slit-like recess 29.

In accordance with an alternative embodiment which is likewise illustrated in FIG. 3, a connector 26 extends over the whole length of the cooling body. In this case it is possible that the connector 26 is secured to the cooling body by means of a plurality of attachment screws 7. A material with comparable thermal expansion coefficients should fundamentally be selected for the connector 27 and the cooling body. Essentially the same demands are made on the material in the case of the cooling body and also in the case of the connector, namely good thermal conductivity and also good electrical conductivity. Copper or copper alloys have proved to be particularly suitable for this purpose. Through the use of materials with the same or similar coefficients of thermal expansion, the connector and the cooling body will expand by the same amount, so that impermissible stresses can not result, either in the attachment screw 7 or in the connector 26. A plurality of target segments (9′, 9″, 9′″ . . . ) can then be received in one connector 26.

In accordance with a further embodiment which is not shown in FIG. 3, the connector 26 could also be designed to be integral with the cooling body. The slit-like recesses 29 would then extend over the whole inner side 21 of the cooling body. In this connection crossed, channel like structures can also be used, so that target segments 9 can be attached to crossing points. Accordingly ribs which cross would also be possible instead of a simple rib 14 which would have the advantage that on the assembly of the target segment 9 its position is also fixed.

As in the first embodiment the thermal transfer also takes place between the target segment 9 and the target segment side surface of the slit-like recess 29 via the rib 14 of the target segment, through the connector 26 via the internal thread 28 and a contact lamella 3 optionally arranged in the interior thread 28 into the attachment screw 7 and also from the attachment screw 7 directly to the cooling body or, alternatively to this, via the sleeve 6 to the cooling body 13. The contact lamella 3 is either part of the attachment screw 7, as is illustrated in the upper part of FIG. 4, or however of the internal thread 28 of the connector 26, as is illustrated in the lower part of FIG. 4. The sleeve 6 is illustrated in FIG. 4 not in direct contact to the coolant which flows through the coolant channels 17. Contact lamellae 11 can be arranged within the slot-like recesses 29 so that an improvement of the current transfer and of the heat transfer and a compensation for length changes, which occur through heating up of the target, can be achieved as in the embodiments described with respect to FIG. 1 or FIG. 2.

The variant of the installation of the sleeve 6 illustrated in FIG. 4 can also be applied to the embodiment according to FIG. 2. The sleeve 6 is screwed into the cooling body or pressed into it. For this purpose receiving means 20 are provided in the cooling body, which are bores for the attachment screw 7 and/or the sleeve 6. As an alternative the sleeve can also have a fixed connection to the attachment screw 7, i.e. a screw connection or comparable shape matched or form locked connection or a pressed connection. A forked plug device 12 can also be received in the slit-like recess 29, as will be described in the following embodiments in accordance with FIG. 5 to FIG. 8. The forked plug device 12 includes in particular a slit-like recess which contains contact lamellae at its inside.

In a further embodiment in accordance with FIG. 5 the target holder 1 is simultaneously formed as a cooling system. The target holder 1 includes the cooling body 13 in which grooves 30 are located, into each of which at least one forked plug device 12 can be received. The cooling body 13 comprises a material of good thermal and electrical conductivity, such as in particular copper or low alloy copper. The forked plug device 12 is provided with contact lamellae 11, which likewise consist of material with good thermal and electrical conductivity, in particular low alloy copper. The contact lamellae 11 can be galvanically coated for the reduction of the contact resistance. A contact resistance of this kind is always present between the surfaces bordering on one another of two directly adjacent bodies lying next to one another in areal contact, particularly if these are bodies made of different materials, as are the target segment and the target holder in this case. A reduced thermal transfer takes place at a boundary surface of this kind due to the surface roughness and the distances to the oppositely disposed surface caused by this, which can be improved by the galvanic coating i.e. by the filling up of this surface roughness. The T-nuts and the attachment screws are left out in the present embodiment as is shown in FIG. 6. The rib 14 of the target segment 9 does not extend across the whole height of the target segment in FIG. 5 or FIG. 6. It is possible to provide further connecting means in the intermediate spaces, which are not shown in detail. Thus conical sliders, eccentric shafts, locking devices by means of plug contacts, tension springs or pneumatically operating plates can be used in order to guarantee a good retention of the target segment 9 in the forked plug device 12. Alternatively the possibility also exists of providing one of the aforementioned connecting means or a combination of the same instead of the forked plug device 12, so that the target segment is attached in the cooling body 13 itself.

A section through the arrangement of two adjoining target segments (9, 9′) is shown in FIG. 6. Each target segment includes a rib 14, which is received by a forked plug device 12, with contact lamellae 11 being provided at the side walls of and/or in the base region of the forked plug device. A part of the only schematically illustrated contact lamellae 11 is visible because the rib 14 has a smaller longitudinal dimension than the groove 30 in which the forked plug device 12 is fitted. To improve the thermal transfer the rib 14 can also extend over the largest part of the longitudinal dimension of the groove. The rib 14 should be able to expand unimpeded in the longitudinal direction, so that the introduction of thermal stresses into the target segment is avoided.

A further embodiment is not illustrated in which a series of grooves lying above one another or a row of grooves lying next to each other is combined to a single channel in which a succession of forked plug devices 12 is located. By means of spring elements the manner of operation of which corresponds to the contact lamella, forked plug devices of this kind can be received in the groove 30 without danger of being lost and also thermal expansions are compensated via the spring tension.

In accordance with a further embodiment in accordance with FIG. 7 and FIG. 8 the target segments can be plugged directly to the cooling body 13. In certain materials this necessity arises for reasons of difficulty of processing them mechanically or chemically by means of a material removing process. Pressed powder or sintered powder are to be named as an example, which were pressed into the shape of a cuboid target segment and for which subsequent alterations in shape are hardly possible. Additionally the processing costs can be reduced by the design of the plug connection, and the material costs can be reduced and the installation can be simplified. The connection of the target segments to the cooling body and the power connection takes place directly via the machined ribs 14 by means of the forked plug devices 12. The attachment of the forked plug devices 12 to the cooling body takes place, in contrast to the previous embodiment, not by plugging into grooves of the cooling body but by means of a bonded connection, such as for example an adhesive connection. Contact lamellae 11, so-called forked plug lamellae are inserted into the forked plug devices 12. It is also possible, as an alternative, to either braze or screw the forked plug devices onto the cooling body or to machine them out of the cooling body by means of a chip-forming machining process such as milling.

The target segments are plugged and fixed directly into these forked plug devices. The target segments are machined using suitable machining methods (according to material: e.g. EDM, milling) in such a way that their rib fits precisely and with firm contact into the forked plug device 12 of the cooling body 13. Milling or EDM (electrical discharge machining) are used in particular as machining methods. Electrical discharge machining is a high precision machining process, by means of which material is cut or drilled. A machining of even extremely hard, tough or brittle material types is made possible by means of electro-physical vaporisation by the application of an electrical potential to an electrode.

The best coating results can be achieved with the following dimensions for the target in which the width of the target amounts to 10 to 1000 mm, in particular 25 to 500 mm, preferably 80 to 140 mm.

The width of the target segment lies preferably in the range of 0.05 to 10 mm, in particular in a range of 0.05 to 50 mm, particularly preferably in a range of 0.05 to 30 mm.

Optimum coating results can be achieved at a distance of the component to be coating from the target of 10 to 1000 mm, in particular of 20 to 500 mm, preferably of 20 to 150 mm.

In accordance with any one of the previous embodiments the target segments 9 can be plugged into the target holding apparatus 1 and can be removed again in this manner. Individual target segments can thus also be replaced in all versions completely independently of the other target segments. A large effective thermal transfer surface arises by means of the areal contact from the target segments to the forked plug devices, so that the target holder apparatus is directly connected to the cooling system.

The heat arising in the target segment can then be led away simply, so that a high cooling rate can be achieved.

Very soft materials come into consideration as material for the target segments, in particular pure aluminium or magnesium. For these materials the poor ability to solder them has been a limiting factor up to now for the increase of the power input for the acceleration of the coating method. Through the coupling in of higher currents the duration of the application of a layer can be shortened by an increased sputtering rate in particular for the application in an HS-PVD method.

The universal nature of the use of target segments in combination with one of the above described coating apparatuses is shown by the fact that very hard or brittle materials such as McrAlY can be energised with at least the same power input as ductile coating materials.

A target which includes a plurality of target segments is used in a method for the coating of a component. For this method a sputtering source is required which includes the target and also a gas for the transport of sputtered coating material to the component and the method includes the steps of: contact of the gas with the target surface, releasing of particles out of the target surface, transport of the released particles with the flow of gas, coating of the component with particles from the flow of gas with the flow of gas proportionally releasing the particles of the component to be coated from each target segment. The particles include charged particles such as in particular ions and/or neutral particles, such as atoms in particular. For the carrying out of the sputtering method the sputtering source including a target which contains the previously described target segments, impact producing means, in other words gas atoms and/or ions and also moving means, in particular a moved gas flux are needed. The impact producing means contact the target in order to release particles from the surface of the target by means of their impulse-like impact on the target surface using the impact energy of the incident impact producing means. A moving means serves for the transport of the sputtered particles from the sputtering source to a component to be coated.

In particular, in accordance with the previously described method, particles are released from the target segments by the stream of gas in such a way that the proportion of the different coating materials or coating material combinations on the component corresponds to the proportion of the target segments with corresponding layer materials or layer material combinations on the target, so that the component is proportionally coated with a first coating material or a first coating layer material combination of a first target segment and with a second coating material or a second coating material combination of a second target segment.

In accordance with an advantageous embodiment the proportion of the different coating materials or layer material combinations sputtered by the flow of gas is altered by a gas distribution unit movable relative to the target. The proportional releasing of coating material from each target segment is based on the following relationship which has been established experimentally in the composition of the layers when varying the proportion of coating materials which are different from one another and which could, moreover, be proved mathematically. The association between the arrangement of the target segments of different layer materials and the layer composition achievable on the coated component results from a statistical analysis which takes into account that particles sputtered from a target are deposited onto a target segment again which is located at a short distance from the component to be coated, after they have travelled a certain distance, until the end of the target at the component side has been reached and the particles are deposited onto the surface of the component to be coated.

At a certain power input the mean path travelled by a particle located at a certain point, i.e. on a first target segment with the pre-determined composition, from its sputtering to its renewed deposition at another place of the first target segment or on a second target segment which is arranged between the first target segment and the component to be coated is known. From the whole distance to be travelled by the particle from the target segment to the component to be coated and from the duration of a single sputtering and deposition sequence the duration up to the deposition of each particle can be calculated with the assumption of the constant speed of flow of gas.

This means that a particle originally located on a target segment which is lying further away from the component to be coated, requires a longer period of time to be deposited on the component than a particle which is arranged at a smaller distance from the component to be coated. Thus per unit of time more particles of the composition are deposited on the component to be coated which are arranged on target segments which are closer to the component to be coated, because they have fewer sputtering and deposition sequences to run through. Through the arrangement of target segments with particles of certain composition at defined points of the target, the composition of the coating on the component can be adjusted exactly by exploiting the knowledge of this fact.

In the last paragraph a particle should include a charged particle, in other words an ion or a neutral particle, in particular an atom and/or a molecule formed from a plurality of the afore-named groups or of a particle of crystalline or amorphous structure.

The use of target segments results in the possibility of arranging different materials on one target and, on taking the sputtering and deposition sequences into account, of predicting in which amount and at which speed each of the materials are deposited on the component.

After the conclusion of each coating process a component of a different coating composition can be produced by means of the alteration of the position of the target segments, so that individual coating solutions can be realised by means of the use of target segments.

Alternatively to, or in combination with the previous solutions it is possible to vary the speed and/or the amount of gas. A variably positionable gas distributor can be provided in particular. Depending on its position the gas distributor covers all the target segments or only some of them, depending on its position, so that the point in time at which different regions of the target are sputtered can be freely set. A variation of this kind can be used in particular for the manufacture of multiple layered coatings. Moreover, very thin layers can be produced since the position of the gas distributor can be altered as fast as desired. By means of a variable gas distributor and/or the arrangement of target segments for the setting of a certain layer composition monomolecular or monoatomic layers can be produced. Layers of this kind have a layer thickness in the nano range and are suitable for the manufacture of a layer transfer from metallic to ceramic layers to which end TGO layers (thermally grown oxides) are used today with a layer thickness of a few micrometres.

### REFERENCE NUMERAL LIST

1. Target holder
2. Cooling body external wall
3. Contact lamella
4. Screw head of the securing screw
5. Plate spring
6. Sleeve
7. Securing screw
8. T-nut
9. Target segment
10. Contact lamella for the T-nut
11. Contact lamella for the target segment
12. Forked plug device
13. Cooling body
14. Rib
15. External wall
16. Screening apparatus
17. Coolant passage
18. Inlet coolant
19. Outlet coolant
20. Receiving means
21. Inner side of the cooling body
22. Cylinder of the T-nut
23. Appended part
24. Groove in the target segment
25. Internal thread T-nut
26. Connector
27. Contact lamella
28. Internal thread connector
29. Slot-like recess
30. Groove
31. Rounded surface
32. Recess
33. Groove in the T-nut
34. Locking element
35. First region of the contact lamella
36. Second region of the contact lamella
37. Rib

1. A target for a sputtering source, wherein the target can be subdivided into a plurality of exchangeable target segments (9) and each target segment (9) contains coating material, wherein each target segment (9) borders on at least two adjacent target segments (9′, 9″), wherein each target segment can be connected to a base body (2, 13, 15) by means of at most one securing means (7, 8, 10) characterised in that the securing means and the target segment (9) have an intermediate space in which an electrically and thermally conductive means (6, 10, 11, 12, 27) is arranged, so that a uniform current strength can be distributed over the surface of the target segment (9) and also the heat arising on the target segment can be dissipated uniformly into the base body.

2. A target for a sputtering source in accordance with claim 1, wherein the electrically an thermally conductive means includes a contact lamella (10, 11, 27).

3. A target for a sputtering source in accordance with claim 1, wherein the securing means (7, 8, 10) includes a plug connection.

4. A target in accordance with claim 3, wherein a plug connection (8, 12) is provided for a plurality of target segments (9, 9′, 9″, 9′″, 9″″).

5. A target for a sputtering source in accordance with claim 1, wherein the base body (2, 13, 15) includes a cooling body (13), onto which each target segment (9) can be electrically and thermally coupled.

6. A target for a sputtering source in accordance with claim 1, wherein each target segment (9) is completely comprised of coating material.

7. A target for a sputtering source in accordance with claim 1, wherein at least one target segment (9) includes a first layer material or a first combination of layer materials, which differ from the layer material or the combination of layer materials of a second target segment (9′, 9″, 9′″, 9″″).

8. A coating source for a gas flow sputtering method in accordance with claim 1.

9. A method for the coating of a component including a sputtering source, a target in accordance with claim 1, and also a gas for the transport of sputtered coating material to the component, the method including the steps of: contact of a gas with the target surface, release of particles from the target surface, transport of the released particles with the flow of gas, the coating of the component with particles from the flow of gas, characterised in that the flow of gas proportionally releases the particles of the component to be coated from each target segment.

10. A method in accordance with claim 9, wherein the flow of gas releases particles from the target segments in such a way that the proportion of different layer materials or layer material combinations on the component corresponds to the proportion of the target segments (9, 9′, 9″, 9′″, 9″″) with corresponding layer materials or layer material combinations on the target, so that the component is proportionally coated with a first layer material or a first layer material combination of a first target segment (9) and with a second layer material or a second layer material combination of a second target segment (9′, 9″, 9′″, 9″″).

11. A method in accordance with claims 9, wherein the proportion of different layer materials or layer material combinations sputtered by the flow of gas is altered by a gas distribution unit which is movable relative to the target.

12. A method in accordance with any claim 9, wherein the gas includes an inert gas, in particular argon and/or the gas is formed as a quasi neutral plasma.
